(19) United States
(12) Patent Application Publication
(10) Pub. No.: US 2007/0190821 A1
(43) Pub. Date: Aug. 16, 2007

(54) System and method for computer-aided plate punching

(75) Inventors: Xin-Zhong Huang, Shenzhen (CN); Xin-Mei Chen, Shenzhen (CN); Yun-Liang Mi, Shenzhen (CN); Yun Shi, Shenzhen (CN); Ping-Hua Zheng, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,863

(22) Filed: Oct. 16, 2006

(30) Foreign Application Priority Data
Dec. 27, 2005 (CN) 200510121386.2

(51) Int. Cl. H05K 1/00

(52) U.S. Cl. 439/79

(57) ABSTRACT

A method for computer-aided plate punching is disclosed. The method includes the steps of reading and configuring processing data; reading a design drawing of a workpiece as a processing diagram; selecting needed figures from the processing diagram, and configuring template attributes to confirm contour of the workpiece; selecting operation modes and cutters for processing orifices; processing the orifices and generating cutters information; selecting operation modes and cutters for processing slots; processing the slots and generating cutters information; optimizing the cutters information, and generating a list of cutters; and converting the list of cutters into corresponding CNC codes. A related system is also disclosed.

### FIELD OF THE INVENTION

The present invention generally relates to systems and methods in computer-aided manufacturing, and more particularly, to a system and method for computer-aided plate punching.

### RELATED ART OF THE INVENTION

Nowadays competitions between enterprises are more and more fierce. In order to remain competitive, improving efficiency has become more important in many enterprises. With improved performances and decrease in price of computer hardware, computers are now widely adopted in many computer-aided activities, such as computer-aided instruction (CAI), computer-aided test (CAT), computer-aided plate punching, and so forth. Therefore, speed and quality in the above activities are greatly improved.

Generally speaking, the process of computer-aided plate punching includes: selecting figures, building a template, generating cutters information, and finally forming computer numeric control (CNC) codes. However, by far most of the systems or methods, which relate to computer-aided plate punching, can't deal with complex design drawings of workpieces, hence slowing down accuracy and efficiency in punching work.

Therefore, what is needed is a system and method for computer-aided plate punching, which can deal with complex design drawings of workpieces, thus accuracy and efficiency can be enhanced enormously.

### SUMMARY

One preferred embodiment provides a system for computer-aided plate punching. The system includes a reading module, a setting module, a selecting module, a processing module and a generating module. The reading module is configured for reading processing data and a design drawing of a workpiece as a processing diagram. The setting module is configured for setting the read data, and setting template attributes and figure attributes of the processing diagram. The selecting module is configured for selecting template information and figure information based upon the set template attributes and figure attributes, and selecting operation modes and cutters for processing the workpiece. The processing module is configured for deleting unrelated information in the processing diagram according to the selected template information and figure information, and processing the workpiece according to the selected operation modes and cutters. The generating module is configured for generating and optimizing cutters information while processing the workpiece, generating a list of cutters according to the optimized cutters information, and converting the list of cutters into corresponding CNC codes.

Another preferred embodiment provides a method for computer-aided plate punching. The method includes the steps of: (a) reading and setting processing data; (b) reading a design drawing of a workpiece as a processing diagram; (c) selecting needed figures from the processing diagram, and setting template attributes to confirm contour of the workpiece; (d) selecting operation modes and cutters for processing orifices; (e) processing the orifices and generating cutters information; (f) selecting operation modes and cutters for processing slots; (g) processing the slots and generating cutters information; (h) optimizing the cutters information, and generating a list of cutters; and (i) converting the list of cutters into corresponding CNC codes.

Other objects, advantages and novel features of the embodiments will be drawn from the following detailed description together with the attached drawings.

### BRIEF DESCRIPTION OF THE DRAWINGS

FIG. 1 is a schematic diagram of hardware configuration and an application environment of a system for computer-aided plate punching in accordance with a preferred embodiment;

FIG. 2 is a schematic diagram of main function modules of the system of FIG. 1;

FIG. 3 is a flow chart of a preferred method for computer-aided plate punching by utilizing the system of FIG. 1;

FIG. 4 is a flow chart of details of one step of FIG. 3, namely processing slots; and

FIG. 5 is a schematic diagram of optimizing traces of cutters in accordance with a preferred embodiment.

### DETAILED DESCRIPTION OF THE PREFERRED EMBODIMENTS

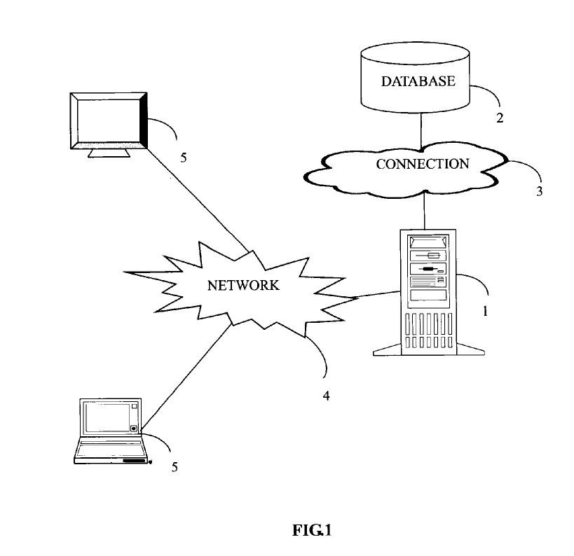

FIG. 1 is a schematic diagram of hardware configuration and an application environment of a system for computer-aided plate punching in accordance with a preferred embodiment. The application environment may typically include a server 1, a database 2, and at least one client computer 5. The server 1 is connected with the database 2 via a connection 3, and is connected with the client computer 5 via a network 4.

The server 1 is configured for saving design drawings of workpieces, processing diagrams, and figures generated while processing the workpieces. Processing the workpieces basically includes processing orifices and processing slots of the workpieces.

The database 2 is used for saving all processing data of the workpieces. The processing data includes initial data settings, operation modes data, cutters data, orifices data, and slots data.

The connection 3 is a database connection that can be an open database connection (ODBC), or a Java database connection (JDBC). The network 4 is an electronic network, which may be the Internet, an Intranet, or any other type of network.

The client computer 5 includes a system for plate punching (hereinafter “the system 10”), and provides graphics user interface (GUI). By using the GUI, all the design drawings, processing diagrams, statuses, and so on while processing the workpieces, can be conveniently seen.

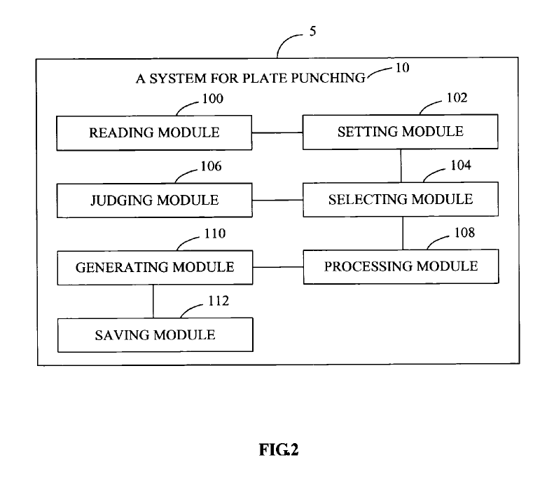

FIG. 2 is a schematic diagram of main function modules of the system 10. The system 10 mainly includes a reading module 100, a setting module 102, a selecting module 104, a judging module 106, a processing module 108, a generating module 110 and a saving module 112.

The reading module 100 is used for reading the processing data from the database 2 via the server 1. The reading module 100 is also used for reading a corresponding design drawing of a workpiece from the server 1 as a processing diagram.

The setting module 102 is used for configuring the processing data read above, and configuring template attributes and figure attributes of the processing diagram.

The selecting module 104 is configured for selecting needed figures of the processing diagram and selecting template information and figure information based upon the template attributes and figure attributes configured by the setting module 102. The selecting module 104 can select operation modes and cutters used while processing the workpiece; also, the selecting module 104 may select to mill corners or drill holes when the slots are processed.

The judging module 106 can determine whether to continue cutting, and determine whether the selecting module 104 has selected milling corners or drilling holes.

The processing module 108 is used for deleting unrelated template information and figure information in the processing diagram, and connecting conterminous figures according to the figures selected. The processing module 108 can also generate and optimize traces of cutters, and process the orifices and the slots according to the selected operation modes and cutters.

The generating module 110 is used for generating and optimizing cutters information while processing the workpiece, and generating a list of cutters according to the optimized cutters information. Also, the generating module 110 can convert the list of cutters into corresponding CNC codes.

The saving module 112 is used for saving the CNC codes converted by the generating module 110.

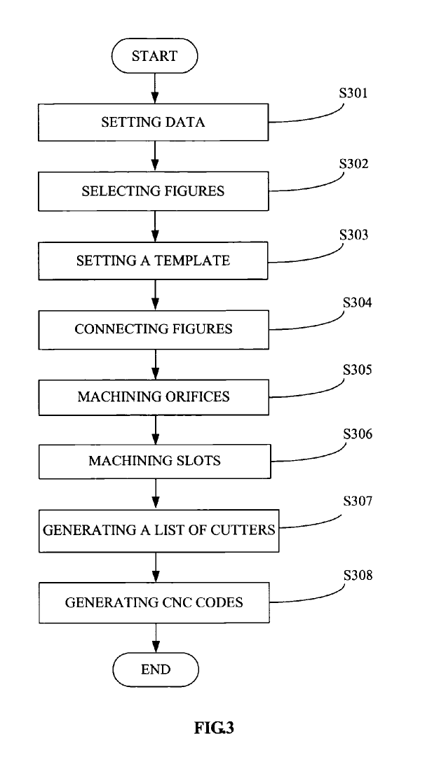

FIG. 3 is a flow chart of a preferred method for computer-aided plate punching by utilizing the system 10.

In step S301, the reading module 100 reads initial data settings, operation modes data, and cutters data from the database 2 via the server 1. Then, the setting module 102 configures the data read by the reading module 100 such as material of a workpiece, for example. In step S302, the reading module 100 reads a corresponding design drawing of a workpiece from the server 1 as the processing diagram. The selecting module 104 selects figures of the processing diagram that are needed for processing the orifices and the slots according to figure attributes, and the processing module 108 deletes unrelated figures according to the selection.

In step S303, the setting module 102 configures template attributes of the processing diagram, so that the contour of the workpiece can be confirmed. In the step S304, the processing module 108 connects conterminous figures according to the selected figures.

In the step S305, the selecting module 104 selects the operation modes and cutters read by the reading module 100 for processing orifices based on the figures that have been selected or connected. The reading module 100 reads orifices data from the database 2 via the server 1. The setting module 102 configures the orifices data, such as orifice diameters, cutting counts, cutting depth, etc. The processing module 108 processes the orifices so as to generate template information and figure information. Then, the setting module 102 configures template attributes and figure attributes. The selecting module 104 selects needed template information and figure information according to the attributes configured by the setting module 102; and the processing module 108 deletes unrelated template information and figure information. The generating module 110 generates cutters information according to the selected template information and figure information.

In the step S306, the selecting module 104 selects the operation modes and cutters read by the reading module 100 for processing the slots based on the figures, which have been selected or connected. The reading module 100 reads the slots data from the database 2 via the server 1. The setting module 102 configures the slots data according to the selected operation modes and cutters. The processing module 108 generates and optimizes traces of cutters for processing the slots, and processes the slots. Meanwhile, the generating module 110 generates corresponding cutters information while processing the slots.

In the step S307, the generating module 110 optimizes all the generated cutters information. Then, the generating module 110 generates a list of cutters after the optimization. In the step S308, the generating module 110 converts the list of cutters into corresponding CNC codes. The saving module 112 saves the CNC codes.

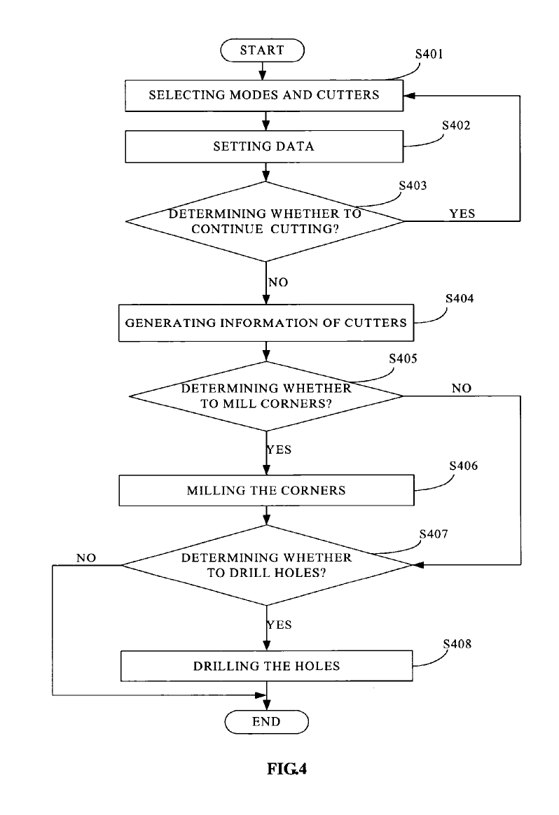

FIG. 4 is a flow chart of details of step S306, namely processing slots.

In step S401, the selecting module 104 selects the operation modes and cutters read by the reading module 100 for processing the slots based on the figures that have been selected or connected. The selecting module 104 may also select whether to mill corners or whether to drill holes when the slots are processed. In step S402, the reading module 100 reads slots data from the database 2 via the server 1, and the setting module 102 configures slots data such as cutting depth, cutting width, cutting counts and so on, on the processing diagram.

In step S403, the judging module 106 judges whether to continue cutting. If the user selects to continue cutting, the procedure returns to the step S401. Otherwise, in step S404, the processing module 108 generates and optimizes traces of cutters, and then processes the slots. Simultaneously, the generating module 110 generates corresponding cutters information when the slots are processed.

In step S405, the judging module 106 determines whether the selecting module 104 has selected to mill corners. If the selecting module 104 has selected to mill corners, in step S406, the processing module 108 mills the corners. The generating module 110 generates corresponding cutters information simultaneously. Otherwise, if the selecting module 104 has not selected to mill corners, in step S407, the judging module 106 determines whether the selecting module 104 has selected to drill holes. If the selecting module 104 has selected to drill holes, in step S408, the processing module 108 drills the holes. The generating module 110 generates corresponding cutters information at the same time. Otherwise, if selecting module 104 has not selected to drill holes, the procedure ends.

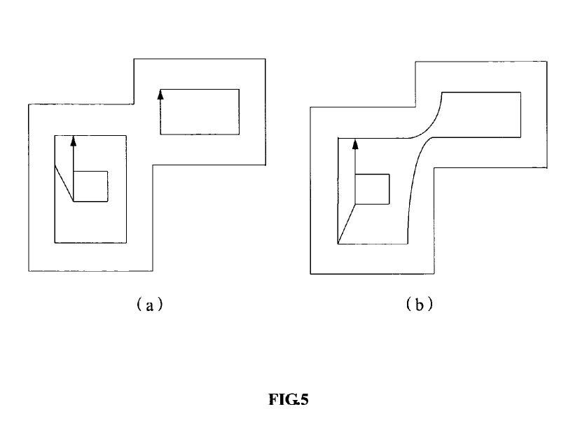

FIG. 5 is a schematic diagram of optimizing traces of cutters in accordance with a preferred embodiment.

Optimization of traces means that many dispersed traces are integrated into fewer traces, so that cutting counts can be reduced. FIG. 5(a) shows traces before being optimized, which are divided into two parts and need two cuttings. The processing module 108 joins the two parts with two circles as shown in FIG. 5(b), so that the two parts can be connected into one trace and can be completed by cutting once.

It should be emphasized that the above-described embodiments of the present invention, particularly, any “preferred” embodiments, are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure, and the present invention is protected by the following claims.

What is claimed is:

1. A system for computer-aided plate punching, the system comprising a reading module configured for reading processing data and a design drawing of a workpiece as a processing diagram;
a setting module configured for configuring the read data, and configuring template attributes and figure attributes of the processing diagram;
a selecting module configured for selecting template information and figure information based upon the configured template attributes and figure attributes, and selecting operation modes and cutters for processing the workpiece;
a processing module configured for deleting unrelated information in the processing diagram according to the selected template information and figure information, and processing the workpiece according to the selected operation modes and cutters; and
a generating module for generating and optimizing cutters information while processing the workpiece, generating a list of cutters according to the optimized cutters information, and converting the list of cutters into corresponding CNC codes.

2. The system according to claim 1, wherein the processing data comprise initial data settings, operation modes data, cutters data, orifices data and slots data.

3. The system according to claim 1, wherein the selecting module is further used for selecting whether to mill corners or whether to drill holes when the slots are processed.

4. The system according to claim 3, further comprising a judging module for determining whether to continue cutting, determining whether milling the corners has been selected, and determining whether drilling the holes has been selected; and
a saving module for saving the converted CNC codes.

5. The system according to claim 1, wherein the processing module is further used for generating and optimizing traces of the cutters.

6. A method for computer-aided plate punching, the method comprising the steps of
reading and configuring processing data;
reading a design drawing of a workpiece as a processing diagram;
selecting needed figures from the processing diagram, and configuring template attributes to confirm contour of the workpiece;
selecting operation modes and cutters for processing orifices;
processing the orifices and generating cutters information;
selecting operation modes and cutters for processing slots;
processing the slots and generating cutters information;
optimizing the cutters information, and generating a list of cutters; and
converting the list of cutters into corresponding CNC codes.

7. The method according to claim 6, further comprising the step of saving the CNC codes.

8. The method according to claim 6, wherein the step of processing the orifices and generating cutters information comprises the steps of
reading and configuring processing data for processing the orifices;
processing the orifices;
generating template information and figure information during the processing process;
selecting needed template information and figure information according to the template attributes and figure attributes; and
generating cutters information.

9. The method according to claim 6, wherein the step of processing the slots and generating cutters information comprises the steps of
selecting whether to mill corners or whether to drill holes when the slots are processed;
reading and configuring processing data for processing the slots;
generating traces for processing the slots, and optimizing the traces;
processing the slots, and generating cutters information;
milling the corners and generating cutters information if milling corners is selected when the slots are processed; and
drilling the holes and generating cutters information if drilling holes is selected when the slots are processed.
